(19) United States
(12) Patent Application Publication
(10) Pub. No.: US 2006/0050549 A1
(43) Pub. Date: Mar. 9, 2006

(54) Electro-resistance element and electro-resistance memory using the same

(75) Inventors: Hideaki Adachi, Osaka (JP); Yasunari Sugita, Osaka (JP); Akihiro Odagawa, Osaka (JP)

Correspondence Address: McDERMOTT WILL & EMERY LLP, 600 13th Street, N.W., Washington, DC, 20005-3096, US

(73) Assignee: MATSUSHITA ELECTRIC INDUSTRIAL CO., LTD., Osaka (JP)

(21) Appl. No.: 11/267,198

(22) Filed: Nov. 7, 2005

Related U.S. Application Data
(63) Continuation of application No. PCT/JP05/14037, filed on Aug. 1, 2005.

(30) Foreign Application Priority Data
Aug. 2, 2004 (JP) 2004-225349

(51) Int. Cl. G11C 11/00

(52) U.S. Cl. 365/148

(57) ABSTRACT

A electro-resistance element with good heat treatment stability under a hydrogen-containing atmosphere and a electro-resistance memory with good resistance change characteristics and productivity are provided. The electro-resistance element has two or more states in which electric resistance values are different, and is switchable from one of the states selected from the two or more states into another by application of a predetermined voltage or current. The electro-resistance element includes a pair of electrodes, and an oxide semiconductor layer sandwiched by the pair of electrodes and having a perovskite structure, and the conductivity type of the oxide semiconductor layer is n-type. The electro-resistance memory is provided with the electro-resistance element.

### BACKGROUND OF THE INVENTION

1. Field of the Invention

The present invention relates to a electro-resistance element the resistance value of which changes by application of voltage or current, and to a electro-resistance memory using the same.

2. Related Background Art

Memory elements are used in a wide variety of fields as essential electronic components that are important to support today's information-driven society. In recent years, as portable information terminals have become increasingly popular, demands for miniaturization of memory elements have been escalating, and non-volatile memory elements are no exception. However, as the scale of device miniaturization is approaching the nanometer range, a decrease in charge capacity C per information unit (bit) has become a problem with conventional charge storage type memory elements (typically DRAMs: Dynamic Random Access Memories). Although various attempts have been made to obviate this problem by improving manufacturing processes, there is a concern over the future technological limit.

As a memory element that is less prone to the adverse effects originating from miniaturization, a non-volatile memory element that records information by a change in electric resistance R, not by a change in charge capacity C, has attracted attention. As this kind of the memory element, Ovshinsky et al. reports an element using a chalcogen compound (TeGeSb) (see JP 2002-512439T (Published Japanese translation of PCT application), for example), and Ignatiev et al. reports an element using a p-type perovskite oxide having a p-type conduction (Pr_{0.7}Ca_{0.3}MnO₃: p-type PCMO) (see U.S. Pat. No. 6,204,139).

The element proposed by Ovshinsky et al., however, utilizes a resistance change associated with a crystalline-amorphous phase change of the above-mentioned chalcogen compound (the element is referred to as a phase change memory element, and the phase change of the chalcogen compound is controlled by applying heat to the element), in which problems remain in miniaturization and response speed of the element.

The element proposed by Ignatiev et al. is an element that utilizes a resistance change of the p-type PCMO by applying an electrical pulse (the element is referred to as a electro-resistance element); in order to construct a memory cell array using the element, the element needs to be used in combination with a semiconductor element (a transistor, a diode, or the like) for selecting the element when recording and reading information. In this case, it is necessary to perform a high-temperature heat treatment (typically about 400° C. to 500° C.) under a hydrogen-containing atmosphere for the purpose of, for example, reducing wiring resistance, to improve the switching performance of the semiconductor element. The heat treatment, however, tends to deteriorate resistance change characteristics of the element using a p-type perovskite oxide such as the p-type PCMO.

It is an object of the present invention to provide a electro-resistance element that exhibits good heat treatment stability under a hydrogen-containing atmosphere, and a electro-resistance memory that includes the electro-resistance element and thereby exhibits good resistance change characteristics and productivity.

### SUMMARY OF THE INVENTION

A electro-resistance element of the present invention is a electro-resistance element having two or more states in which electric resistance values are different, and being switchable from one of the two or more states into another by application of a predetermined voltage or current, the electro-resistance element including: a pair of electrodes, and an oxide semiconductor layer sandwiched by the pair of electrodes and having a perovskite structure, wherein the oxide semiconductor layer has n-type conductivity.

In the electro-resistance element of the present invention, it is preferable that the oxide semiconductor layer contain an oxide semiconductor represented by the formula X¹NiO₃, or an oxide semiconductor represented by the formula X²MnO₃, wherein: X¹ is at least one element selected from Y, La, Ce, Pr, Nd, Sm, Eu, Gd, Tb, Dy, Ho, Er, Yb and Lu, and X² is at least one element selected from alkaline-earth metal elements.

In the electro-resistance element of the present invention, it is preferable that X¹ be at least one element selected from Ce, Pr, Nd, and Sm, and X² be at least one element selected from Ca and Sr.

In the electro-resistance element of the present invention, it is preferable that the oxide semiconductor layer contain an oxide semiconductor represented by the formula X¹₍₁₋ₐ₎X²ₐNiO₃, or an oxide semiconductor represented by the formula X²(_{1-b)}X³_{b}MnO₃, wherein: X¹ is at least one element selected from Y, La, Ce, Pr, Nd, Sm, Eu, Gd, Th, Dy, Ho, Er, Yb and Lu; X² is at least one element selected from alkaline-earth metal elements; and X³ is at least one element selected from Bi, Y, La, Ce, Pr, Nd, Sm, Eu, Gd, Tb, Dy, Ho, Er, Yb and Lu; and a and b in the formulas satisfy the following expressions:
0<a≦0.1, and
0<b≦0.4.

In the electro-resistance element of the present invention, it is preferable that X¹ be at least one element selected from Ce, Pr, Nd, and Sm; X² is at least one element selected from Ca and Sr; and X³ is at least one element selected from La and Bi.

In the electro-resistance element of the present invention, it is preferable that the oxide semiconductor layer contain an oxide semiconductor represented by the formula (Nd_{(1-c)}Ce_{c})₂CuO₄, wherein 0≦c≦0.16.

In the electro-resistance element of the present invention, one electrode selected from the pair of electrodes may be made of a material capable of growing the oxide semiconductor layer on a surface of the one electrode by crystallization growth.

In the electro-resistance element of the present invention, the oxide semiconductor layer may be a layer epitaxially grown on a surface of the one electrode selected from the pair of electrodes.

In the electro-resistance element of the present invention, the one electrode selected from the pair of electrodes may be made of at least one element selected from Pt and Ir.

In the electro-resistance element of the present invention, the one electrode selected from the pair of electrodes may be made of at least one conductive oxide selected from SrTiO₃, SrRuO₃, and SrTiO₃ which is doped with at least one element selected from Nb, Cr, and La.

In the electro-resistance element of the present invention, the predetermined voltage or current may be in a pulse form.

A electro-resistance memory of the present invention includes: at least one or more electro-resistance elements, each having two or more states in which electric resistance values are different from one another and being switchable from one state selected from the two or more states into another by application of a predetermined voltage or current, wherein: each of the electro-resistance elements includes a pair of electrodes, and an oxide semiconductor layer sandwiched by the pair of electrodes and having a perovskite structure; and the oxide semiconductor layer has n-type conductivity.

In the electro-resistance memory of the present invention, two or more of the electro-resistance elements may be aligned in a matrix form.

### BRIEF DESCRIPTION OF THE DRAWINGS

FIG. 1 is a cross-sectional view schematically illustrating one example of a electro-resistance element according to the present invention;

FIG. 2 is a schematic view illustrating one example of a electro-resistance memory according to the present invention;

FIG. 3 a cross-sectional view schematically illustrating the electro-resistance memory according to the present invention;

FIG. 4 is a view for illustrating a method of recording and reading information with the electro-resistance memory according to the present invention;

FIG. 5 is a view for illustrating one example of a method of reading information with the electro-resistance memory according to the present invention;

FIG. 6 is a schematic view illustrating a electro-resistance memory (array) according to the present invention;

FIG. 7A is a process drawing schematically illustrating one example of the method of manufacturing a electro-resistance memory according to the present invention;

FIG. 7B is a process drawing schematically illustrating one example of the method of manufacturing a electro-resistance memory according to the present invention;

FIG. 7C is a process drawing schematically illustrating one example of the method of manufacturing a electro-resistance memory according to the present invention;

FIG. 7D is a process drawing schematically illustrating one example of the method of manufacturing a electro-resistance memory according to the present invention;

FIG. 7E is a process drawing schematically illustrating one example of the method of manufacturing a electro-resistance memory according to the present invention;

FIG. 7F is a process drawing schematically illustrating one example of the method of manufacturing a electro-resistance memory according to the present invention;

FIG. 7G is a process drawing schematically illustrating one example of the method of manufacturing a electro-resistance memory according to the present invention;

FIG. 7H is a process drawing schematically illustrating one example of the method of manufacturing a electro-resistance memory according to the present invention; and

FIG. 71 is a process drawing schematically illustrating one example of the method of manufacturing a electro-resistance memory according to the present invention.

### DETAILED DESCRIPTION OF THE INVENTION

Hereinbelow, preferred embodiments of the present invention are described with reference to the drawings. In the following description, same components are denoted by same reference numerals, and further elaboration thereof may be omitted.

A electro-resistance element of the present invention will be described.

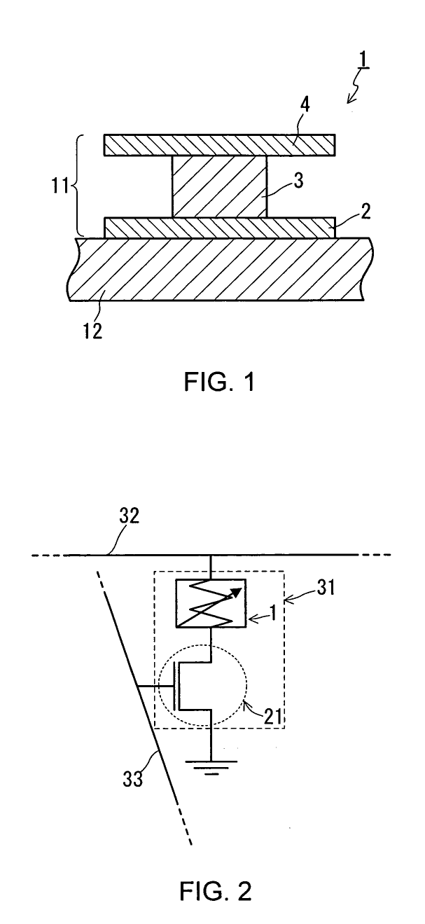

A electro-resistance element 1 shown in FIG. 1 includes a substrate 12, a pair of electrodes comprised of a lower electrode 2 and an upper electrode 4, an oxide semiconductor layer 3 sandwiched by the lower electrode 2 and the upper electrode 4. The lower electrode 2, the oxide semiconductor layer 3, and the upper electrode 4 are arranged on the substrate 12 in that order so that they form a stacked structure 11. The oxide semiconductor layer 3 has a perovskite structure, and its conductivity type is n type.

The electro-resistance element 1 has two or more states in which electric resistance values are different from each other, and the element 1 may be switched from one state selected from the two or more states into another by applying a predetermined voltage or current to the element 1. In the case where the element 1 has two states in which electric resistance values are different (one of the states in which the resistance is relatively high is defined as “state A,” while the other in which the resistance is relatively low is defined as “state B”), the element 1 is switched from state A into state B, or from state B to state A, by application of a predetermined voltage or current.

One example of element that exhibits such a change in electric resistance values is the previously-described element that has a p-type PCMO layer; however, as discussed earlier, the foregoing element tends to cause degradation in its resistance change characteristics by a heat treatment under a hydrogen-containing atmosphere. In contrast, the electro-resistance element of the present invention shows good heat treatment stability under a hydrogen-containing atmosphere because it includes the oxide semiconductor layer 3, which has a perovskite structure and whose conductivity type is n type.

The resistance change rate of the electro-resistance element of the present invention is generally 50% or greater, and may be increased to 200% or greater by selecting the material used for the lower electrode 2 and/or the oxide semiconductor contained in the oxide semiconductor layer 3. Such resistance change characteristics may be obtained even after a heat treatment under a hydrogen-containing atmosphere has been carried out for the element. Therefore, the electro-resistance element of the present invention can be easily applied to various electronic devices (for example, a electro-resistance memory) by combining it with semiconductor elements, and by the combination, an electronic device that has good characteristics (for example, resistance change characteristics) and good productivity can be obtained. It should be noted that the heat treatment under a hydrogen-containing atmosphere is intended to mean, for example, a heat treatment typically at about 400° C. to 500° C. that is performed for the purpose of reducing wiring resistance or the like when the electro-resistance element of the present invention is combined with a semiconductor element. It also should be noted that the resistance change rate is a numerical value that serves as an index of the resistance change characteristics of an element; specifically, it is a value obtained by the expression (R_{MAX}−R_{MIN})/R_{MIN}×100 (%), wherein R_{MAX} denotes the maximum electric resistance value that the element shows, and R_{MIN} denotes the minimum electric resistance value that the element shows.

Although the configuration of the oxide semiconductor layer 3 is not particularly limited as long as its crystal structure is a perovskite structure and its conductivity type is n-type, it is preferable that the oxide semiconductor layer 3 contain an oxide semiconductor shown below.

1. Oxide Semiconductor Represented by the Formula X¹NiO₃

In the formula, X¹ is at least one element selected from Y, La, Ce, Pr, Nd, Sm, Eu, Gd, Tb, Dy, Ho, Er, Yb and Lu, preferably at least one element selected from Ce, Pr, Nd and Sm.

2. Oxide Semiconductor Represented by the Formula X²MnO₃

In the formula, X² is at least one element selected from alkaline-earth metal elements (Ca, Sr, and Ba), preferably at least one element selected from Ca and Sr.

3. Oxide Semiconductor Represented by the Formula X¹₍₁₋ₐ₎X²ₐNiO₃

In the formula, X¹ is at least one element selected from Y, La, Ce, Pr, Nd, Sm, Eu, Gd, Tb, Dy, Ho, Er, Yb, and Lu, preferably at least one element selected from Ce, Pr, Nd, and Sm. X² is at least one element selected from alkaline-earth metal elements, preferably at least one element selected from Ca and Sr. The atomic fraction a in the above formula satisfies the expression 0<a≦0.1.

4. Oxide Semiconductor Represented by the Formula X²(_{1-b)}X³_{b}MnO₃

In the formula, X² is at least one element selected from alkaline-earth metal elements, preferably at least one element selected from Ca and Sr. X³ is at least one element selected from Bi, Y, La, Ce, Pr, Nd, Sm, Eu, Gd, Th, Dy, Ho, Er, Yb, and Lu, preferably at least one element selected from La and Bi. The atomic fraction b in the above formula satisfies the expression 0<b≦0.4.

5. Oxide Semiconductor Represented by the Formula (Nd_{(1-c)}Ce_{c})₂CuO₄

The atomic fraction c in the above formula satisfies the expression 0≦c≦0.16.

The thickness of the oxide semiconductor layer 3 is generally in the range of from 1 nm to 1000 nm.

The lower electrode 2 is basically adequate as long as it has electrical conductivity, but it should preferably be made of a material capable of growing the oxide semiconductor layer 3 on a surface thereof by crystallization growth. This makes it possible to form the oxide semiconductor layer 3 having a stable crystal structure on the lower electrode 2, and makes the formation of the oxide semiconductor layer 3 on the lower electrode 2 easier, thereby allowing the electro-resistance element 1 to have good productivity and exhibit stable resistance change characteristics.

Representative examples of the material capable of growing the oxide semiconductor layer 3 by crystallization growth include Pt (platinum) and Ir (iridium). In other words, it is preferable that in the electro-resistance element 1, the lower electrode 2 is made of at least one element selected from Pt and Ir. When the lower electrode 2 is made of a metal, a region in the lower electrode 2 near the surface that is in contact with the oxide semiconductor layer 3 may be oxidized. For example, it is possible that a surface film of iridium oxide (iridium oxide film) may be formed on a surface of the lower electrode 2 made of iridium and the oxide semiconductor layer 3 is arranged on the surface film.

It is preferable that the lower electrode 2 be made of at least one conductive oxide selected from SrTiO₃, SrRuO₃, and doped SrTiO₃. The doped SrTiO₃ is doped with at least one element selected from Nb, Cr, and La. These conductive oxides are the materials capable of growing oxide semiconductor layer 3 by crystallization growth on their surfaces, so when the lower electrode 2 is made of any of these conductive oxides, the oxide semiconductor layer 3 can be epitaxially grown on a surface thereof. In other words, the oxide semiconductor layer 3 in this case is a layer epitaxially grown on a surface of the lower electrode 2.

The upper electrode 4 is basically adequate as long as it has electrical conductivity, and it may be made of such substances as Au (gold), Pt (platinum), Ru (ruthenium), Ir (iridium), Ti (titanium), Al (aluminum), Cu (copper), and Ta (tantalum), as well as an iridium-tantalum alloy (Ir—Ta) and a indium tin oxide (ITO).

The configuration of the electro-resistance element of the present invention is not particularly limited as long as the lower electrode 2, the oxide semiconductor layer 3, and the upper electrode 4 are provided and the oxide semiconductor layer 3 is sandwiched by the lower electrode 2 and the upper electrode 4. For example, the substrate 12 shown in FIG. 1 may be provided as needed. As shown in FIG. 1, when the stacked structure 11 is arranged on the substrate 12, the substrate 12 may be a silicon substrate, for example, in which case it becomes easy to combine the electro-resistance element of the present invention with a semiconductor element. A region in the substrate 12 near the surface that is in contact with the lower electrode 2 may be oxidized (an oxide film may be formed on a surface of the substrate 12).

The junction area in the electro-resistance element of the present invention is generally in the range of from 0.01 μm² to 10 mm² and may be set at any area within the foregoing range.

A predetermined voltage or current may be applied to the electro-resistance element 1 via the lower electrode 2 and the upper electrode 4. By the application of a predetermined voltage or current, the foregoing states are changed in the element 1 (for example, from the state A to the state B), but the state prior to the change (for example, the state B) is retained until a predetermined voltage or current is again applied to the element 1. When the voltage or current is applied, the state is changed again (for example, from the state B to the state A). It should be noted that the predetermined voltage or current applied to the element 1 may not necessarily be the same between when the element 1 is in the state A and when the element 1 is in the state B, and the magnitude, polarity, flow direction, and the like may be varied depending on the state of the element 1. That is, in the present specification, it is sufficient that “a predetermined voltage or current” is such a “voltage or current” that the element 1 in a certain state can be changed into another state that is different from the certain state.

Thus, the electro-resistance element 1 can retain its electric resistance value until a predetermined voltage or current is applied to the element 1. Therefore, by combining the element 1 and a mechanism for detecting the foregoing states in the element 1 (that is, a mechanism for detecting the electric resistance value of the element 1) and assigning a bit to each of the foregoing states (for example, the state A is assigned to “0” and the state B is assigned to “1”), it is possible to construct a non-volatile electro-resistance memory (a memory element or a memory array in which two or more memory elements are aligned).

It is preferable that a voltage or current applied to the electro-resistance element 1 be in a pulse form. When constructing an electronic device such as a memory using the element 1, it becomes possible to reduce power consumption and improve switching efficiency in the electronic device. The shape of the pulse is not particularly limited and may be at least one shape selected from, for example, a sine waveform, a rectangular waveform, and a triangular waveform.

Applying voltage to the electro-resistance element 1 is preferable, in which case it becomes easier to achieve miniaturization of the element 1 and size reduction of the electronic device constructed with the use of the element 1. One example is as follows. In the case of the electro-resistance element 1 having the foregoing two states, the state A and the state B, a potential difference-applying mechanism for creating a potential difference between the lower electrode 2 and the upper electrode 4 may be connected to the element 1. For example, the state of the element 1 may be changed from the state A to the state B by applying a bias voltage such that the potential of the upper electrode 4 becomes positive with respect to the potential of the lower electrode 2 (positive bias voltage) to the element 1, while the state of the element 1 may be changed from the state B to the state A by applying a bias voltage such that the potential of the upper electrode 4 becomes negative with respect to the potential of the lower electrode 2 (negative bias voltage) to the element 1 (in other words, by applying a voltage the polarity of which is reversed from the polarity at the time when changing from the state A to the state B).

FIG. 2 illustrates one example of a electro-resistance memory (element) in which the electro-resistance element of the present invention and a transistor (MOS field effect transistor: MOS-FET), which is one type of the semiconductor element, are combined.

The electro-resistance memory element 31 shown in FIG. 2 is provided with the electro-resistance element 1 and a transistor 21. The electro-resistance element 1 is electrically connected to the transistor 21 and a bit line 32. The gate electrode of the transistor 21 is electrically connected to a word line 33, and the remaining electrode of the transistor 21 is grounded. Such a memory element 31 enables the detection of the foregoing states in the electro-resistance element 1 (that is, the detection of the electric resistance value of the element 1) and the application of a predetermined voltage or current to the element 1, using the transistor 21 as a switching element. For example, in the case where the element 1 shows two states in which electric resistance values are different, the memory element 31 shown in FIG. 2 may be used as a 1-bit electro-resistance memory element.

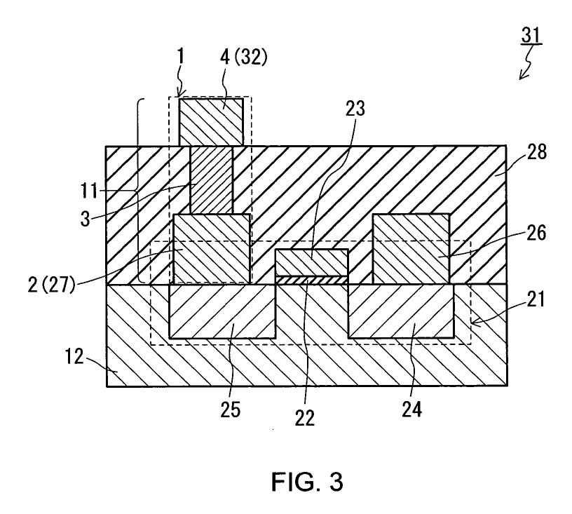

FIG. 3 illustrates one example of a specific configuration of a electro-resistance memory (element) of the present invention. In a memory element 31 shown in FIG. 3, the transistor 21 and the electro-resistance element 1 are formed on a silicon substrate (substrate 12), and the transistor 21 and the electro-resistance element 1 are integrated. Specifically, a source 24 and a drain 25 are formed on the substrate 12, and a source electrode 26 is formed on the source 24 while the lower electrode 2 that also serves as a drain electrode 27 formed on the drain 25. A gate electrode 23 is formed on the surface of the substrate 12 and between the source 24 and the drain 25 with a gate insulating film 22 interposed therebetween, and the oxide semiconductor layer 3 and the upper electrode 4 are disposed on the lower electrode 2 in that order. The gate electrode 23 is electrically connected to a word line (not shown), and the upper electrode 4 also serves as a bit line 32. An interlayer insulating layer 28 is disposed over the substrate 12 so as to cover the surface of the substrate 12, the electrodes, and the oxide semiconductor layer 3 to prevent electrical leakage between the electrodes.

It is sufficient that the transistor 21 has a common configuration of a MOS-FET.

The interlayer insulating layer 28 may be made of an insulating material such as SiO₂ or Al₂O₃, or may have a stacked structure of two or more kinds of materials. For the insulating material, a resist material may be used other than SiO₂ and Al₂O₃. In the case of using a resist material, the interlayer insulating layer 28 can be easily formed by spinner coating or the like, and moreover, an interlayer insulating layer 28 the surface of which is planar can be formed easily even when forming the interlayer insulating layer 28 on a surface that is not planar.

Although in the example shown in FIG. 3, the electro-resistance memory is constructed by combining a electro-resistance element and a MOS-FET, the structure of the electro-resistance memory of the present invention is not particularly limited, and may be combined with any semiconductor element, for example, other types of transistors or diodes.

Moreover, although the memory element 31 shown in FIG. 3 has a structure in which the electro-resistance element 1 is disposed directly above the transistor 21, the transistor 21 and the electro-resistance element 1 may be disposed at distant locations from each other, and the lower electrode 2 and the drain electrode 27 may be electrically connected by a connecting electrode. To simplify the manufacturing process of the memory element 31, it is preferable that the electro-resistance element 1 and the transistor 21 be disposed at distant locations from each other; however, when the electro-resistance element 1 is disposed directly above the transistor 21, as shown in FIG. 3, the occupied area by the memory element 31 becomes small and therefore it is possible to realize a electro-resistance memory array having a higher density.

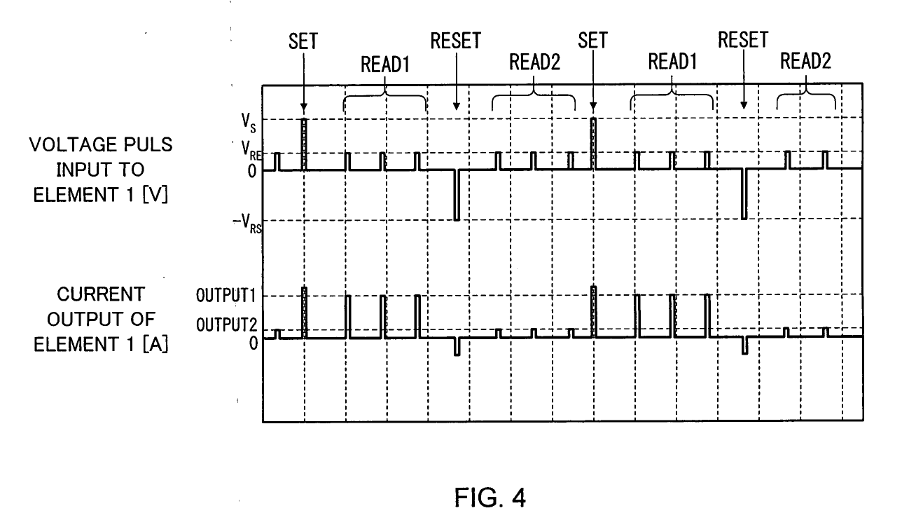

Recording of information into the memory element 31 may be performed by application of a predetermined voltage or current to the electro-resistance element 1, and reading of the information recorded in the element 1 may be performed by varying the magnitude of the voltage or current applied to the element 1 from that in the recording. As the method of recording and reading information, one example of the method in which a pulsed voltage is applied to the element 1 is explained with reference to FIG. 4.

In the example shown in FIG. 4, it is assumed that the electro-resistance element 1 has such resistance change characteristics as follows; the element 1 is turned from a state in which the electric resistance is relatively large (state A) to a state in which the electric resistance is relatively small (state B) by application of a positive bias voltage having a magnitude equal to or greater than a certain threshold value (V₀), while the element 1 is turned from the state in which the electric resistance is relatively small (state B) to the state in which the electric resistance is relatively large (state A) by application of a negative bias voltage having a magnitude equal to or greater than a certain threshold value (V_{0′}). It is assumed that the positive bias voltage means a voltage such that the potential of the upper electrode 4 with respect to the potential of the lower electrode 2 becomes positive, and the negative bias voltage means a voltage such that the potential of the upper electrode 4 with respect to the lower electrode 2 becomes negative. The magnitude of each bias voltage corresponds to the magnitude of the potential difference between the lower electrode 2 and the upper electrode 4.

It is assumed that the initial state of the electro-resistance element 1 is the state A. When a positive bias voltage V_{S} (|V_{S}|≧V₀) in a pulse form is applied between the lower electrode 2 and the upper electrode 4, the element 1 is switched from the state A to the state B (SET in FIG. 4). The positive bias voltage applied at this time is denoted as SET voltage.

Here, if a positive bias voltage that is smaller than the SET voltage and whose magnitude is less than V₀ is applied to the element 1, the electric resistance value of the element 1 can be detected as a current output of the element 1 (READ1 and OUTPUT1 in FIG. 4). The detection of the electric resistance value can also be done by applying to the element 1 a negative bias voltage the magnitude of which is less than V_{0′}. These voltages applied for detecting the electric resistance value of the element 1 are denoted as READ voltage (V_{RE}). The READ voltage may be in a pulse form, as shown in FIG. 4, in which case it is possible to reduce the power consumption and improve the switching efficiency in the memory element 31, as in the case where the SET voltage is in a pulse form. Since the application of READ voltage does not change the state of the element 1 (state B), the same electric resistance value can be detected even when READ voltage is applied a plurality of times.

Next, when a negative bias voltage V_{RS} (|V_{RS|≧V}_{0′}) in a pulse form is applied between the lower electrode 2 and the upper electrode 4, the element 1 is switched from the state B to the state A (RESET in FIG. 4). The negative bias voltage applied at this time is denoted as RESET voltage.

Here, if READ voltage is applied to the element 1, the electric resistance value of the element 1 can be detected as the current output of the element 1 (READ2 and OUTPUT2 in FIG. 4). In this case as well, since the application of READ voltage does not change the state of the element 1 (state A), the same electric resistance value can be detected even when READ voltage is applied a plurality of times.

Thus, it is possible to perform recording and reading of information to the memory element 31 by application of voltage in a pulse form, and the magnitude of the output current from the element 1 obtained by the reading varies corresponding to the state of the element 1. Here, the state in which the output current is relatively large (OUTPUT1 in FIG. 4) is defined as “1” while the state in which the output current is relatively small (OUTPUT2 in FIG. 4) is defined as “0”; thereby, the memory element 31 can record information “1” by the SET voltage and record information “0” (erase information “1”) by the RESET voltage.

To apply a voltage in a pulse form to the electro-resistance element 1 in the memory element 31 shown in FIG. 3, the transistor 21 may be turned ON by the word line to apply a voltage through the bit line 32.

It is preferable that the magnitude of READ voltage be generally about ¼ to 1/1000 of the magnitude of SET voltage and RESET voltage. Specific values of the SET voltage and RESET voltage are generally within the range of from 0.1 V to 20 V, preferably within the range of from 1 V to 12 V, although they may depend on the configuration of the electro-resistance element 1.

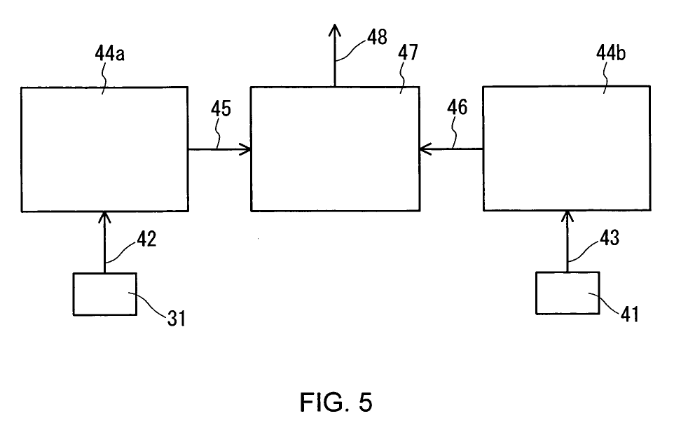

In order to enhance the accuracy of the detection, it is preferable that the detection of the electric resistance value of the element 1 be performed by detecting a difference from a reference resistance value (for example, a reference output current value) that is obtained by applying READ voltage in the same manner as in the foregoing to a reference element prepared separately from the element to be detected. In the method illustrated in FIG. 5, an output signal 48 is detected that is obtained by feeding, into a differential amplification circuit 47, an output 45 obtained by amplifying an output 42 from the memory element 31 by a negative feedback amplification circuit 44a and an output 46 obtained by amplifying an output 43 from a reference element 41 by a negative feedback amplification circuit 44b.

When two or more memory elements 31 are aligned in a matrix form as shown in FIG. 6, a non-volatile and random access type electro-resistance memory (array) 34 can be constructed. With the memory array 34, it becomes possible to record information into a memory element 31a, which is located at a coordinate (Bn, Wn), and to read information from the memory element 31a, by selecting one bit line (Bn) selected from two or more bit lines 32 and one word line (Wn) selected from two or more word lines 33.

As shown in FIG. 6, when two or more memory elements 31 are aligned in a matrix form, at least one memory element 31 may be made a reference element.

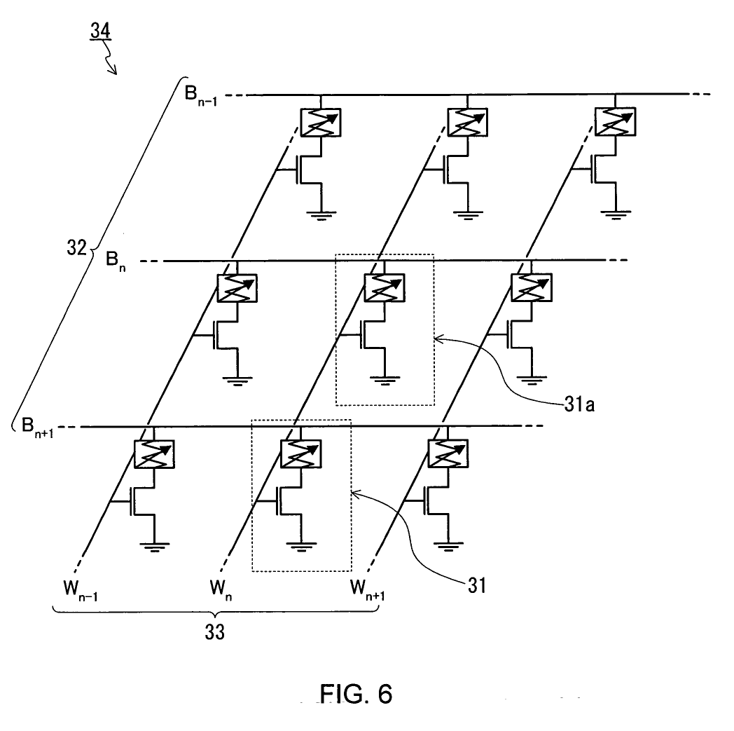

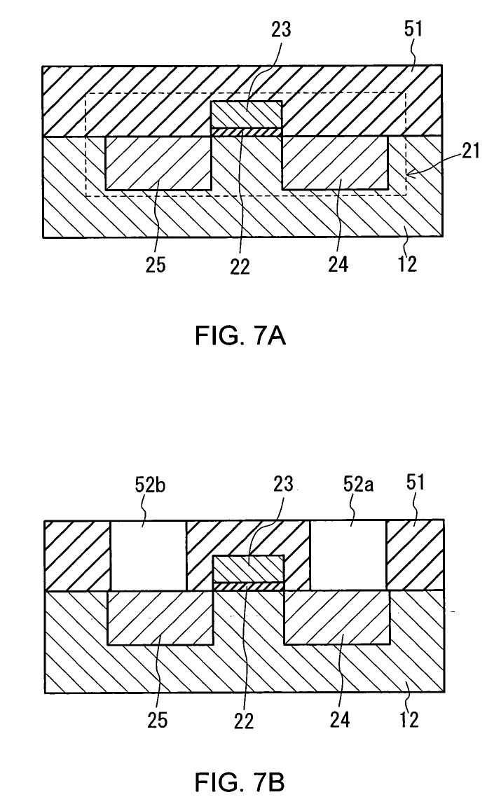

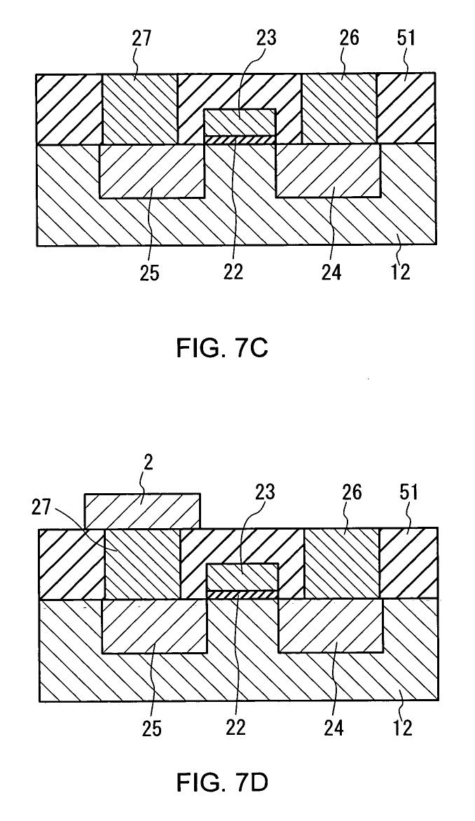

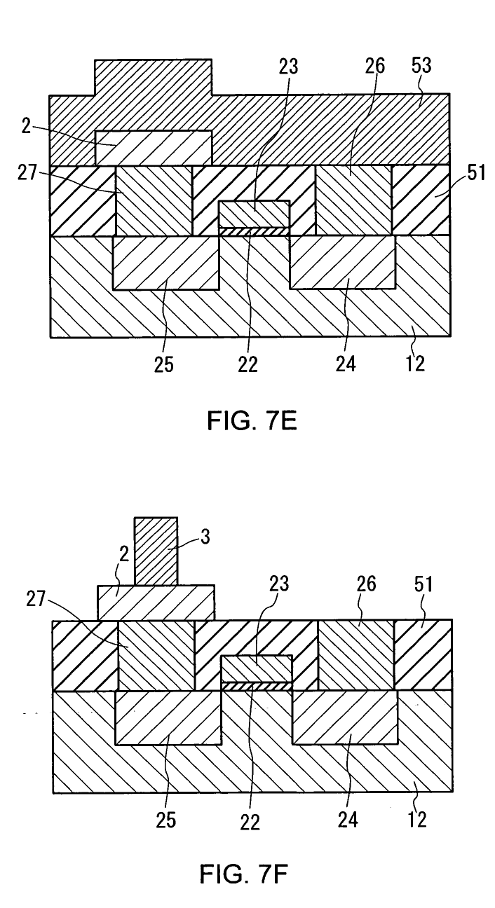

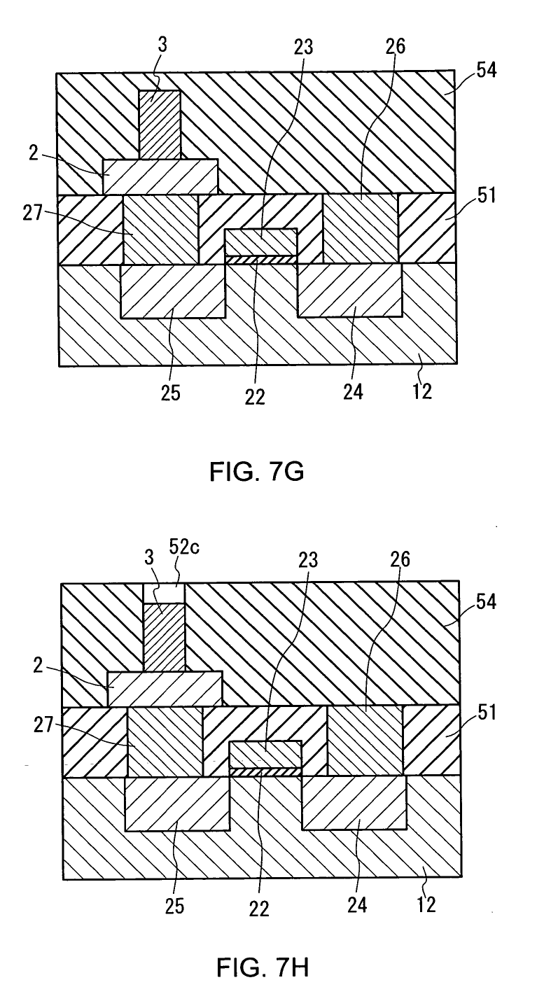

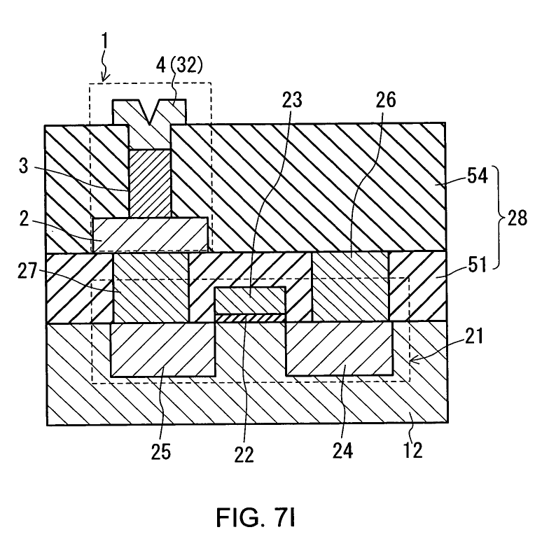

The electro-resistance element of the present invention and the electronic device provided with the electro-resistance element of the present invention can be fabricated by applying manufacturing processes of semiconductors or the like. One example of the method of manufacturing the memory element 31 shown in FIG. 3 is described with reference to FIGS. 7A to 7I.

First, a substrate 12 is prepared, on which a transistor 21, which is a MOS-FET, is formed (FIG. 7A). On the substrate 12, a source 24, a drain 25, a gate insulating film 22, and a gate electrode 23 are formed. An insulating oxide film 51 made of an insulating material such as SiO₂ is disposed over the substrate 12 so as to entirely cover the surface of the substrate 12, the gate insulating film 23, and the gate electrode 23.

Next, contact holes 52a and 52b that reach the source 24 and the drain 25 in the transistor 21 are formed through the insulating oxide film 51 (FIG. 7B), and a conductor is deposited into the contact holes 52a and 52b to form a source electrode 26 and a drain electrode 27 (FIG. 7C). When forming the source electrode 26 and the drain electrode 27, it is preferable that the surface of the deposited conductor be planarized so as to form buried electrodes as shown in FIG. 7C.

Next, a lower electrode 2 is formed on the formed drain electrode 27 so that the electrical connection with the drain electrode 27 can be ensured (FIG. 7D). Subsequently, an oxide semiconductor 53 is deposited over the entire surface including the formed lower electrode 2 (FIG. 7E), and thereafter the oxide semiconductor 53 is micromachined into a predetermined shape to form an oxide semiconductor layer 3 (FIG. 7F). Next, an insulating layer 54 is deposited entirely over the insulating oxide film 51, the source electrode 26, the lower electrode 2, and the oxide semiconductor layer 3 (the whole exposed portion) (FIG. 7G), and a contact hole 52c is formed at a location in the insulating layer 54 in which an upper electrode 4 is to be disposed (FIG. 7H). Lastly, a conductor is deposited in the formed contact hole 52c to form the upper electrode 4, thereby forming the memory element 31 shown in FIG. 3 (FIG. 7I).

The processes shown in FIGS. 7A to 7I can be realized by common thin-film formation processes and micromachining processes. Examples of the techniques that may be applied to form the layers include pulse laser deposition (PLD), ion beam deposition (IBD), cluster ion beam, and various sputtering techniques such as RF, DC, electron cyclotron resonance (ECR), helicon, inductively coupled plasma (ICP), and facing target sputtering, as well as molecular beam epitaxy (MBE) and ion plating. Other than these PVD (Physical Vapor Deposition) techniques, it is also possible to use CVD (Chemical Vapor Deposition), MOCVD (Metal Organic Chemical Vapor Deposition), a plating method, MOD (Metal Organic Decomposition), or a sol-gel method.

For the micromachining of the layers, the following techniques, which are commonly used in the manufacture processes for semiconductors and magnetic device (for example, magnetoresistive elements such as GMR and TMR), may be used in combination: physical or chemical etching such as ion milling, RIE (Reactive Ion Etching), and FIB (Focused Ion Beam), and photolithography techniques using a stepper for forming micro patterns and an EB (Electron Beam) technique. The planarization of the interlayer insulating layer and the surface of the conductor deposited in the contact holes may be performed by, for example, CMP (Chemical Mechanical Polishing), cluster-ion beam etching, or the like.

### EXAMPLES

Hereinbelow, the present invention is described in further detail with reference to Examples. It should be noted that the present invention is not limited to Examples described below.

In Examples 1 to 4, PrNiO₃ (hereinafter “PNO”) or the like is used as the n-type oxide semiconductor having a perovskite structure to fabricated a electro-resistance element as illustrated in FIG. 1

### Example 1

First, a Si substrate on a surface of which a thermally oxidized film (SiO₂ film) was formed was employed as a substrate 12, and a metal mask A having an aperture in a rectangular shape (0.5 mm wide and 100 mm long) was disposed on the Si substrate. Thereafter, a Pt layer (400 nm thick) was deposited thereon as a lower electrode 2. After the metal mask A was removed, the size of the deposited Pt layer was found to be 0.5 mm×10 mm, which corresponded to the foregoing aperture.

Next, a metal mask B having an aperture in a square shape (1 mm×1 mm) was disposed on the deposited Pt layer, and thereafter, a PNO layer (200 nm thick) was deposited thereon as an oxide semiconductor layer 3. After the metal mask B was removed, the size of the deposited PNO layer was found to be 1 mm×1 mm, which corresponded to the foregoing aperture. The metal mask B was disposed so that the center of its aperture (in a rectangular aperture, the point of intersection of two liner lines connecting the opposing vertexes is defined as the center) matches the center of the Pt layer on which the metal mask B is disposed. After the depositing, the crystal structure of the PNO layer was confirmed by an X-ray diffraction measurement, and it was found that the PNO layer had a perovskite structure.

Next, the metal mask A was disposed on the deposited PNO layer so that the center of the aperture thereof matched the center of the PNO layer and the longitudinal axis of the aperture was orthogonal to the longitudinal axis of the Pt layer, which was the lower electrode 2, and then, a Pt layer (300 nm thick) was deposited as the upper electrode 4. After removing the metal mask A, the size of the deposited Pt layer was found to be 0.5 mm×10 mm, which corresponded to the foregoing aperture. Thus, a electro-resistance element (sample 1) was fabricated, in which the longitudinal axis of the lower electrode 2 was orthogonal to the longitudinal axis of the upper electrode 4 and the junction area of the PNO layer was 0.5 mm×0.5 mm.

The depositing of the Pt layer and the PNO layer was carried out by magnetron sputtering, in which the Pt layer was deposited under an argon atmosphere at a pressure of 0.7 Pa, and the PNO layer was under an argon-oxygen mixture atmosphere (oxygen partial pressure was 30% of the argon partial pressure) at a pressure of 6 Pa. In depositing the PNO layer, the temperature of the Si substrate was set in the range of from 600° C. to 800° C. (mainly 700° C.), and the applied electric power was set at 80 W.

Apart from the fabrication of the sample 1, a electro-resistance element was fabricated in which a Pr_{0.7}Ca_{0.3}MnO₃ (p-type PCMO) layer was deposited in place of the PNO layer, as a Comparative Example to Example 1 (Comparative Example Sample A). The sample A was fabricated according to the method described in U.S. Pat. No. 6,204,139. Specifically, using a (100) LaAlO₃ substrate as the substrate, YBa₂Cu₃O₇ (hereinafter “YBCO”) was deposited at a thickness of 200 nm by a laser ablation technique and a 400 nm-thick p-type PCMO layer was further deposited thereon. The depositing of the YBCO layer and the p-type PCMO layer was conducted while the substrate temperature was set at 750° C. under an oxygen atmosphere at a pressure of 20 Pa (150 mm Torr) with a laser output of 1.5 J/cm². For the upper electrode, a Pt layer (300 nm thick) was deposited in the same manner as used for the sample 1, and the size and shape of the p-type PCMO layer was made the same as the size and shape of the PNO layer in sample 1. The junction area of the p-type PCMO layer was the same as that of the sample 1, 0.5 mm×0.5 mm.

The samples 1 and A thus fabricated were evaluated in terms of their resistance change rates by applying voltage in a pulse form as shown in FIG. 4. The evaluation of resistance change rate was conducted in the following manner.

Using a pulse generator, a voltage of 5 V (positive bias voltage) as the SET voltage shown in FIG. 4, a voltage of −5V (negative bias voltage, magnitude 5 V) as the RESET voltage, and a voltage of 1 V (positive bias voltage) as the READ voltage were randomly applied between the upper electrode and the lower electrode in each of the samples (the pulse width of the voltages was 250 ns). After applying the SET voltage and/or the RESET voltage, the electric resistance values of the elements were calculated from the current values read out by the application of the READ voltage, and the resistance change rate of each of the elements was obtained from the equation (R_{Max}−R_{Min})/R_{Min}×100 (%), where R_{Max} is the maximum value of the calculated electric resistance values and R_{Min} is the minimum value thereof.

The results of the evaluation showed that the resistance change rate of the sample 1 was 500%, and the resistance change rate of the sample A was 550%. In fabricating the elements, the junction areas of the PNO layer (sample 1) and the p-type PCMO layer (sample A) were changed by varying the aperture areas of the metal masks A and B in the range of from 0.001 mm² to 10 mm², but the resistance change rates obtained showed almost no change in the sample 1 or A.

Next, in order to evaluate heat treatment stability under a hydrogen-containing atmosphere, the samples 1 and A were placed in a hydrogen-nitrogen mixture gas atmosphere (the mixture gas was allowed to flow at all times and the flow rate of hydrogen to nitrogen was 10%), the temperature was elevated from room temperature to a heat-treatment temperature, 400° C., and the samples were retained at 400° C. for 0.5 hours. Thereafter, each of the samples was cooled to room temperature, and the resistance change rate of each sample was evaluated according to the above-described method. Hereinafter, the term “heat treatment” means a “heat treatment under a hydrogen-containing atmosphere” unless otherwise specified.

The results of the evaluation indicated that the resistance change rate of the sample 1 was 670%, which became greater than that before performing the heat treatment. In contrast, the sample A showed a resistance change rate of 10% or less, indicating that the resistance change characteristics greatly degraded. Furthermore, in the sample A, recording and erasure operations by application of SET voltage and RESET voltage were unstable.

Although the reason why the resistance change characteristics of the sample A degraded by the heat treatment is not clearly understood, the following are possible.

When heat-treating the sample A, the amount of oxygen deficiency increases in the p-type PCMO layer because of the reduction of hydrogen, producing n-type carriers. It is believed that the resistance change characteristics of the p-type PCMO layer greatly degrade due to the n-type carriers. On the other hand, it is presumed that when heat-treating the sample 1, which is the electro-resistance element of the present invention, n-type carriers are also produced in the PNO layer because of a similar reduction. Nevertheless, since the PNO layer itself has n-type conductivity, the PNO layer is not apt to be influenced by the adverse effect on the resistance change characteristics by n-type carriers.

In addition, the fact that the base material of the n-type oxide semiconductor having a perovskite structure, such as PNO, is a Mott insulator might also be a reason why the electro-resistance element of the present invention is not apt to be influenced by the adverse effects on the resistance change characteristics by the foregoing heat treatment. The Mott insulator refers to an insulator in which a gap is created by Coulomb repulsion because it has strong interaction between electrons, and its electron system differs from that of the electron system of general band insulators. It is believed that unlike the band insulator, the Mott insulator does not exhibit simple responses to carrier implantation and therefore is not apt to be affected by the n-type carriers produced during the foregoing heat treatment.

Next, two kinds of electro-resistance elements were fabricated in a similar manner to that of the sample 1, except that a NdNiO₃ layer and a SmNiO₃ layer were deposited as the oxide semiconductor layer 3 in place of the PNO layer, respectively (samples 2 and 3). In addition, a electro-resistance element was fabricated in a similar manner to that of the sample A by depositing a La_{0.65}Ca_{0.35}MnO₃ layer, which is an oxide semiconductor layer having p-type conductivity, in place of the p-type PCMO layer in the sample A (Comparative Example Sample B). The crystal structures of the deposited NdNiO₃ layer and SmNiO₃ layer were confirmed by an X-ray diffraction measurement, and it was found that the respective layers had a perovskite structure.

With the fabricated samples, the same heat treatment as that employed for the samples 1 and A was conducted, and their resistance change rates were evaluated before and after the heat treatment. The results of the evaluation are shown in Table 1. Table 1 also shows the results of evaluation of the resistance change rates in the samples 1 and A. In Table 1, the column for the oxide semiconductor layer 3 of Comparative Example shows the layer in the comparative example sample that exhibits resistance change characteristics.

TABLE 1

| | | Resistance | Resistance |
|---|---|---|---|
| | Oxide | Change Rate (%) | Change Rate (%) |
| | Semiconductor | (Before Heat | (After Heat |
| Sample No. | Layer 3 | Treatment) | Treatment) |
| 1 | PrNiO₃ | 500 | 670 |
| 2 | NdNiO₃ | 350 | 380 |
| 3 | SmNiO₃ | 420 | 430 |
| A | Pr_{0.7}Ca_{0.3}MnO₃ | 550 | 10 or less |
| (Comparative | | | |
| Example) | | | |
| B | La_{0.65}Ca_{0.35}MnO₃ | 550 | 10 |
| (Comparative | | | |
| Example) | | | |

As shown in Table 1, even when the NdNiO₃ layer or the SmNiO₃ layer was used as the n-type oxide semiconductor layer, their resistance change characteristics did not deteriorate by the heat treatment, and moreover the recording and erasure operations after the heat treatment were stable. On the other hand, the sample B showed considerable deterioration in its resistance change characteristics by the heat treatment, as with the sample A.

### Example 2

Using a SrTiO₃ substrate doped with 0.75 wt. % La (STO: La substrate) as the substrate 12, a PNO layer (500 nm thick) as the oxide semiconductor layer 3 was deposited on the STO: La substrate. Since the SrTiO₃ substrate has conductivity when the amount of La doped is in the range of from 0.5 wt. % to 1 wt. %, the STO: La substrate also serves as the lower electrode 2. The depositing of the PNO layer on the STO: La substrate was performed in the same manner as with the sample 1 in Example 1. The crystal structure of the deposited PNO layer was confirmed by an X-ray diffraction measurement, and it was found that the PNO layer had a perovskite structure and was epitaxially grown on the same crystal plane (100) as the surface place of the STO: La substrate.

Next, a metal mask C having a circular aperture (diameter 0.5 mm) was disposed on the deposited PNO layer, and a Ag layer (300 nm thick) was deposited as the upper electrode 4. After removing the metal mask C, the Ag layer deposited had a 0.5 mm-diameter circular shape, which corresponded to the foregoing aperture. Thus, a electro-resistance element (sample 4) was fabricated in which the junction area of the PNO layer was 0.2 mm². The depositing of the Ag layer was conducted by magnetron sputtering under an argon atmosphere at a pressure of 0.7 Pa.

With the sample 4 thus fabricated, its resistance change rate was evaluated in the same manner as in Example 1 and found to be 400%. In fabricating the element, the junction area of the PNO layer was changed in the range of from 0.001 mm² to 10 mm² by varying the aperture area of the metal mask C, but the obtained resistance change rates showed almost no change.

Next, a heat treatment was conducted in the same manner as in Example 1 to evaluate heat treatment stability under a hydrogen-containing atmosphere, and it was found that the resistance change rate of the sample 4 was 520%, which was greater than that before the heat treatment was conducted. Moreover, the recording and erasure operations of the sample 4 were also stable after the heat treatment.

Next, a electro-resistance element (sample 5) was fabricated in the same manner as with the sample 4 except that a Pr_{0.9}Ca_{0.1}NiO₃ layer was deposited as the oxide semiconductor layer 3 in place of the PNO layer. The crystal structure of the deposited Pr_{0.9}Ca_{0.1}NiO₃ layer was confirmed by an X-ray diffraction measurement, and it was found that the Pr_{0.9}Ca_{0.1}NiO₃ layer had a perovskite structure and was epitaxially grown on the same crystal plane (100) as the surface of the STO: La substrate.

With the fabricated sample 5, the same heat treatment as with the sample 4 was conducted to evaluate the resistance change rates before and after the heat treatment. Consequently, it was found that the resistance change rate before the heat treatment was 250%, and the resistance change rate after the heat treatment was 260%. Thus, when using the oxide semiconductor in which a portion of a rare-earth element Pr was substituted by an alkaline earth element Ca as well, it was possible to obtain a electro-resistance element having good heat treatment stability under a hydrogen-containing atmosphere.

### Example 3

A electro-resistance element (sample 6) in which the oxide semiconductor layer 3 is a CaMnO₃ (hereinafter “CMO”) layer was fabricated in a similar manner to that with the sample 1 in Example 1. The depositing of the CMO layer (200 nm thick) was performed by magnetron sputtering and in under an argon-oxygen mixture atmosphere at a pressure of 3 Pa (the oxygen partial pressure was 20% of the argon partial pressure). In depositing the CMO layer, the temperature of the Si substrate was set within the range of from 600° C. to 800° C. (mainly 750° C.), and an electric power applied was set at 80 W. The junction area of the CMO layer was made 0.5 mm×0.5 mm, as with the sample 1. The crystal structure of the deposited CMO layer was confirmed by an X-ray diffraction measurement, and it was found that the CMO layer had a perovskite structure.

With the sample 6 thus fabricated, its resistance change rate was evaluated in the same manner as in Example 1 and found to be 450%. In fabricating the element, the junction area of the CMO layer was changed in the range of from 0.001 mm² to 10 mm² by varying the aperture area of the metal mask, but the obtained resistance change rates showed almost no change.

Next, the sample 6 and the sample A fabricated in Example 1 were evaluated in terms of heat treatment stability under a hydrogen-containing atmosphere (which had different conditions from that in Example 1). The sample 6 and the sample A were placed in a hydrogen-argon mixture gas atmosphere (5 volume % hydrogen), then the temperature was elevated from room temperature to 400° C. (temperature elevation rate: 100° C./hour) and kept at 400° C. for 0.5 hours. Thereafter, the samples were cooled to room temperature (temperature decrease rate: 50° C./hour), and their resistance change rates were evaluated in the same manner as in Example 1.

The results of the evaluation demonstrated that the resistance change rate of the sample 6 was 470%, which was greater than that before performing the heat treatment. In contrast, the resistance change rate of the sample A was 25%, and the resistance change characteristics considerably degraded. Moreover, with the sample A, recording and erasure operations by application of SET voltage and RESET voltage were unstable.

Next, two kinds of electro-resistance elements were fabricated in a similar manner to that with sample 6 by depositing a Ca_{0.6}La_{0.4}MnO₃ layer and a Ca_{0.6}Bi_{0.4}MnO₃ layer as the oxide semiconductor layer 3 in place of the CMO layer, respectively (samples 7 and 8). The crystal structures of the deposited Ca_{0.6}La_{0.4}MnO₃ layer and Ca_{0.6}Bi_{0.4}MnO₃ layer were confirmed by an X-ray diffraction measurement, and it was found that both layers had a perovskite structure.

The fabricated samples were subjected to the same heat treatment as in Example 1 and their resistance change rates before and after the heat treatment were evaluated. The results of the evaluation showed that the resistance change rates of the samples before the heat treatment were 350% (sample 7) and 290% (sample 8), respectively, and the values did not decrease because of the heat treatment. Moreover, both the samples 7 and 8 showed stable recording and erasure operations after the heat treatment.

Next, electro-resistance elements (samples 9 to 11) were fabricated in the same manner as with the sample 6 except that a CMO layer, a Ca_{0.6}La_{0.4}MnO₃ layer, and a Ca_{0.6}Bi_{0.4}MnO₃ layer were deposited respectively as the oxide semiconductor layer 3 and the junction area of the oxide semiconductor layer 3 was set at 1 μm². In order to control the junction area to be 1 μm², photolithography and ion milling were additionally employed when fabricating the samples.

With the fabricated samples 9 to 11, their resistance change rates were measured in the same manner as in Example 1 and found to be 440% (sample 9), 340% (sample 10), and 300% (sample 11), respectively. Additionally, the junction area of the oxide semiconductor layer 3 was varied in the range of from 0.01 μm² to 100 m², but the obtained resistance change rates showed almost no change.

Next, in order to evaluate heat treatment stability under a hydrogen-containing atmosphere, the samples 9 to 11 were subjected to a heat treatment in the same manner as in Example 1 (the heat-treatment temperature was 500° C., however). With all the samples 9 to 11, their resistance change rates did not decrease and their recording and erasure operations were stable.

### Example 4

A electro-resistance element in which the oxide semiconductor layer 3 was a Nd_{1.85}Ce_{0.15}CuO₄ (hereinafter NCCO) layer (sample 12) was fabricated in a similar manner to that used for the sample 1 in Example 1. NCCO is known to be a layered perovskite compound having a K₂NiF₄-type crystal structure.

The depositing of the NCCO layer (200 nm thick) was conduced by magnetron sputtering under an argon-oxygen mixture atmosphere (the oxygen partial pressure being 25% that of the argon partial pressure) at a pressure of 3 Pa. In depositing the NCCO layer, the temperature of the Si substrate was controlled to be within the range of from 600° C. to 800° C. (mainly 650° C.), and an electric power applied was set at 150 W. The junction area of the NCCO layer was set to be 0.5 mm×0.5 mm, as with the sample 1.

As the upper electrode 4, a Au layer was deposited to a thickness of 300 nm in place of the Pt layer in the sample 1. The depositing of the Au layer was conducted by magnetron sputtering under an argon atmosphere at a pressure of 0.7 Pa.

With the sample 12 thus fabricated, its resistance change rate was evaluated in the same manner as in Example 1 and found to be 350%. In fabricating the element, the junction area of the NCCO layer was changed in the range of from 0.001 mm² to 10 mm² by varying the aperture area of the metal mask, but the obtained resistance change rates showed almost no change.

Next, in order to evaluate heat treatment stability under a hydrogen-containing atmosphere, the same heat treatment as in Example 1 was performed. The resistance change rate of the sample 12 was 380%, which was greater than that before the heat treatment. Moreover, the recording and erasure operations of the sample 12 after the heat treatment were also stable.

### Example 5

In Example 5, a memory element 31 as shown in FIG. 3 was fabricated using a PNO layer as the oxide semiconductor layer 3. The fabrication of the memory element 31 was conducted according to the manufacturing steps shown in FIGS. 7A to 7I.

First, a Si substrate 12, as shown in FIG. 7A, was prepared on which a MOS-FET was formed. Next, as shown in FIG. 7B, contact holes 52a and 52b were formed by photolithography. Subsequently, as shown in FIG. 7C, Pt was deposited as a conductor and thereafter the surface planarized by CMP to form a source electrode 26 and a drain electrode 27 that were buried into the contact holes.

Next, as shown in FIG. 7D, a Pt layer (200 nm thick) was formed as a lower electrode 2 on the formed drain electrode 27. After the depositing, the Pt layer was micromachined into a 0.8 μm-diameter circular shape. Subsequently, as shown in FIG. 7E, PNO (400 nm thick) was deposited as an oxide semiconductor 53 over the entire surface including the Pt layer, which is the lower electrode 2. The depositing of PNO was performed by magnetron sputtering under an argon-oxygen mixture atmosphere (the oxygen partial pressure being 30% of the argon partial pressure) at a pressure of 6 Pa while the temperature of the Si substrate was controlled to be in the range of from 600° C. to 800° C. (mainly 700° C.) and the electric power applied to be 80 W.

Next, as shown in FIG. 7F, the deposited PNO was micromachined by photolithography and ion milling into a 0.5 μm-diameter circular shape to form an oxide semiconductor layer 3 made of PNO. Subsequently, as shown in FIG. 7G, a positive photoresist was coated over the entire surface by spin coating, then baked at 120° C. for 30 minutes to form an insulating layer 54. Then, as shown in FIG. 7H, a contact hole 52c (having a 0.35 μm-diameter circular cross-sectional shape) was formed by photolithography at a portion of the insulating layer 54 in which an upper electrode 4 was to be disposed, and a Pt layer (300 nm thick), which serve as the upper electrode 4 and a bit line 32, was deposited within the contact hole 52c. Thus, a memory element (sample 13) as shown in FIG. 3 was fabricated. It should be noted that a word line is formed in advance of the formation of the transistor 21 and is wired in the direction orthogonal to the bit line 32. The Pt layers, which serve as the lower electrode 2 and the upper electrode 4, were deposited by magnetron sputtering under an argon atmosphere at a pressure of 0.7 Pa.

Apart from the fabrication of the sample 13, a memory element (sample C) in which a p-type PCMO layer was deposited in place of the PNO layer was fabricated as a Comparative Example to Example 5 in a similar manner to that with the sample 13. The depositing of the p-type PCMO layer was performed by magnetron sputtering under an argon-oxygen mixture atmosphere at a pressure of 3 Pa (the oxygen partial pressure being 20% of the argon partial pressure) while the substrate temperature was controlled to be 650° C. and the electric power applied to be 100 W.

With the memory element samples 13 and C thus fabricated, hydrogen sintering was performed to reduce the wiring resistance of the MOS-FET. Hydrogen sintering is generally used in semiconductor manufacturing processes. The conditions of the hydrogen sintering were: under a 100% hydrogen atmosphere, a process pressure of 1000 Pa, a heat-treatment temperature of 400° C., and a heat treatment time of 10 minutes.

Next, each of the samples after the heat treatment was tested in terms of the operations as a memory. The operation test was conducted as follows. The MOS-FET is brought into an ON state by voltage application to the gate electrode. Then, as shown in FIG. 4, SET voltage (positive bias voltage, 5 V), RESET voltage (negative bias voltage, magnitude 5 V), and READ voltage (positive bias voltage, 1 V) were applied between the source electrode 26 and the upper electrode 4, and the current values that were output from the samples were measured. The current values were measured by detecting a difference value from a reference current value obtained by applying, to a reference resistor disposed separately from the samples, the same READ voltage applied to the samples.

The results demonstrate that the sample 13 was able to clearly distinguish between the current value at the time when READ voltage was applied after the application of SET voltage and the current value at the time when READ voltage was applied after the application of RESET voltage (in other words, the resistance change characteristics could be confirmed), and it was capable of operate as a memory element. In contrast, such resistance change characteristics were unable to be confirmed with the sample C, which was difficult to operate as a memory element.

Next, with the sample 13 that did not yet undergo the heat treatment, hydrogen sintering was conducted while the heat-treatment temperature was elevated to 500° C., and the operation test as a memory was conducted similarly. Consequently, the resistance change characteristics similar to the case in which the heat treatment temperature was 400° C. were confirmed.

Moreover, two or more samples 13 were aligned in a matrix form to construct a memory array, which was subjected to the hydrogen sintering and then tested. As a result, the operation as a random access type electro-resistance memory was confirmed.

As has been discussed above, the electro-resistance element of the present invention exhibits good heat treatment stability under a hydrogen-containing atmosphere; therefore, it can be easily fabricated by applying various semiconductor manufacture processes when manufacturing the element, and can be applied to various electronic devices by, for example, combining it with a semiconductor element. Moreover, the electro-resistance element of the present invention can retain information as an electric resistance value in a non-volatile manner, and miniaturization of the element is easier than conventional charge storage type memory elements. Examples of the electronic devices using the electro-resistance element of the present invention include non-volatile memories, sensors, and image display devices, which may be used for information communication terminals.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A electro-resistance element having two or more states in which electric resistance values are different, and being switchable from one of the two or more states into another by application of a predetermined voltage or current, the electro-resistance element comprising:
a pair of electrodes, and an oxide semiconductor layer sandwiched by the pair of electrodes and having a perovskite structure, wherein
the oxide semiconductor layer has n-type conductivity.

2. The electro-resistance element according to claim 1, wherein the oxide semiconductor layer contains an oxide semiconductor represented by the formula X¹NiO₃, or an oxide semiconductor represented by the formula X²MnO₃, wherein:
X¹ is at least one element selected from Y, La, Ce, Pr, Nd, Sm, Eu, Gd, Tb, Dy, Ho, Er, Yb and Lu, and
X² is at least one element selected from alkaline-earth metal elements.

3. The electro-resistance element according to claim 2, wherein:
X¹ is at least one element selected from Ce, Pr, Nd, and Sm, and
X² is at least one element selected from Ca and Sr.

4. The electro-resistance element according to claim 1, wherein:
the oxide semiconductor layer contains an oxide semiconductor represented by the formula X¹₍₁₋ₐ₎X²ₐNiO₃, or an oxide semiconductor represented by the formula X²(_{1-b)}X³_{b}MnO₃, wherein:
X¹ is at least one element selected from Y, La, Ce, Pr, Nd, Sm, Eu, Gd, Tb, Dy, Ho, Er, Yb and Lu;
X² is at least one element selected from alkaline-earth metal elements; and
X³ is at least one element selected from Bi, Y, La, Ce, Pr, Nd, Sm, Eu, Gd, Tb, Dy, Ho, Er, Yb and Lu; and
a and b in the formulas satisfy the following expressions:
0<a≦0.1, and
0<b≦0.4.

5. The electro-resistance element according to claim 4, wherein:
X¹ is at least one element selected from Ce, Pr, Nd, and Sm;
X² is at least one element selected from Ca and Sr; and
X³ is at least one element selected from La and Bi.

6. The electro-resistance element according to claim 1, wherein the oxide semiconductor layer contains an oxide semiconductor represented by the formula (Nd_{(1-c)}Ce_{c})₂CuO₄, wherein 0≦c≦0.16.

7. The electro-resistance element according to claim 1, wherein one electrode selected from the pair of electrodes is made of a material capable of growing the oxide semiconductor layer on a surface of the one electrode by crystallization growth.

8. The electro-resistance element according to claim 1, wherein the oxide semiconductor layer is a layer epitaxially grown on a surface of the one electrode selected from the pair of electrodes.

9. The electro-resistance element according to claim 1, wherein the one electrode selected from the pair of electrodes is made of at least one element selected from Pt and Ir.

10. The electro-resistance element according to claim 1, wherein the one electrode selected from the pair of electrodes is made of at least one conductive oxide selected from SrTiO₃, SrRuO₃, and SrTiO₃ which is doped with at least one element selected from Nb, Cr, and La.

11. The electro-resistance element according to claim 1, wherein the predetermined voltage or current is in a pulse form.

12. A electro-resistance memory comprising:
at least one or more electro-resistance elements, each having two or more states in which electric resistance values are different and being switchable from one state selected from the two or more states into another by application of a predetermined voltage or current, wherein:
each of the electro-resistance elements includes a pair of electrodes, and an oxide semiconductor layer sandwiched by the pair of electrodes and having a perovskite structure; and
the oxide semiconductor layer has n-type conductivity.

13. The electro-resistance memory according to claim 12, wherein two or more of the electro-resistance elements are aligned in a matrix form.
